(19) United States
(12) Patent Application Publication
(10) Pub. No.: US 2010/0084180 A1
(43) Pub. Date: Apr. 8, 2010

(54) ELECTRONIC DEVICE WITH A SHIELDING MEMBER

(75) Inventors: SHE-FEN CHIANG, Tu-Cheng (TW); CHUNG-WEN HUANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/411,350

(22) Filed: Mar. 25, 2009

(30) Foreign Application Priority Data
Oct. 6, 2008 (CN) 200820302332.5

(51) Int. Cl. H05K 9/00

(52) U.S. Cl. 174/377; 361/818

(57) ABSTRACT

An electronic device includes a circuit board and a shielding member. The circuit board includes a pair of frames and a plurality of mounting holes disposed between the frames. The pair of frames surround at least one electronic component positioned within an area defined within the pair of frames. The shielding member is configured for shielding the electronic component from electromagnetic interference (EMI), and includes a top wall, a plurality of sidewalls, and a plurality of mounting portion extending from end portions of the sidewalls. The top wall and the sidewalls cooperatively bound a receiving space to receive the at least one electronic component. The mounting portions are received in the corresponding mounting holes to attach the shielding member to the circuit board.

### BACKGROUND

1. Technical Field

The present disclosure generally relates to electronic devices, and more particularly to an electronic device with a shielding member.

2. Description of Related Art

Electromagnetic interference (EMI) occurs between neighboring electronic components or circuits due to inductive coupling therebetween. Sources that may emit EMI include inverters, diodes, transistors, amplifiers, power supplies, and other circuits of electronic devices. Effective performance of electronic devices can be interrupted, obstructed, or degraded by EMI. One popular solution developed to avoid reduce the effects of EMI is to employ a metal shielding member to absorb as much EMI radiation energy as possible. However, there are often gaps between the shielding member and the circuit, and as a result, electromagnetic waves radiated from the EMI sources can leak from the gaps.

Therefore, a need exists in the industry to overcome the described limitations.

### BRIEF DESCRIPTION OF THE DRAWINGS

FIG. 1 is an exploded, isometric view of an electronic device of an exemplary embodiment of the disclosure; and

FIG. 2 is a cross-sectional, assembled view of FIG. 1.

### DETAILED DESCRIPTION OF THE EMBODIMENTS

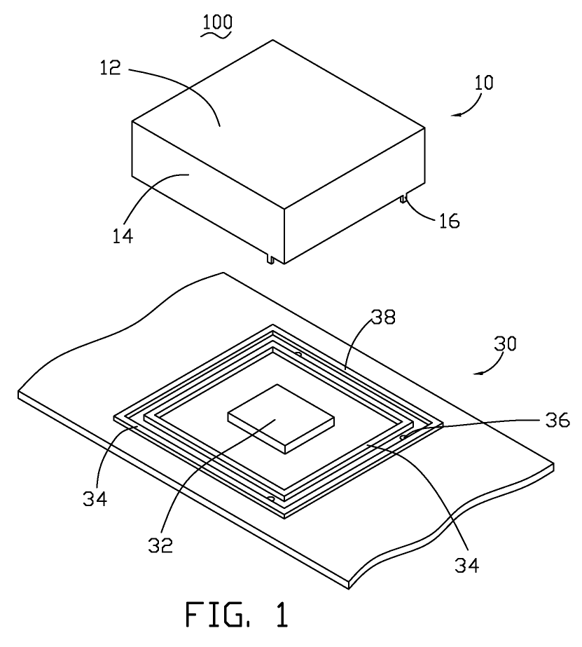

FIG. 1 is an exploded, isometric view of an electronic device 100 of an exemplary embodiment of the present disclosure. The electronic device 100 includes a shielding member 10 and a circuit board 30.

The circuit board 30 includes an electronic component 32, an annular inner frame 34, an annular outer frame 38, and a plurality of mounting holes 36 arranged in different orientations disposed between frames 34, 38. The inner frame 34 surrounds the electronic component 32 and the outer frame 38 surrounds the inner frame 34. In the illustrated embodiment, there are three mounting holes 36. The frames 34, 38 are made of soldering tin, in one example.

In the illustrated embodiment, a height of each of the frames 34, 38 is about 0.1 mm, a width of each of the frames 34, 38 is about 0.25 mm. However, sizes of the frames 34, 38 may be varied depending on the type and size of the electronic component 32.

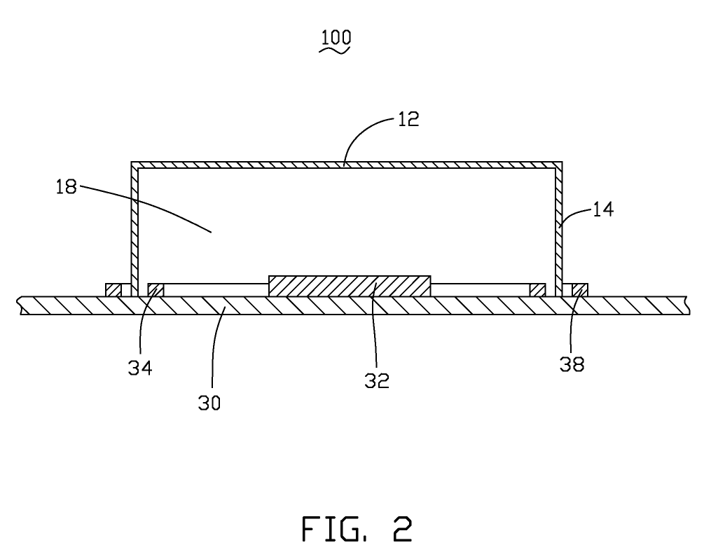

With reference to FIGS. 1-2, the shielding member 10 is configured for protecting the electronic component 32 from electromagnetic interference (EMI), and includes a top wall 12, a plurality of sidewalls 14, and three mounting portions 16 each received in the corresponding mounting hole 36 The sidewalls 14 are connected perpendicularly to the top wall 12. The top wall 12 and the sidewalls 14 cooperatively surround a receiving space 18. The electronic component 32 is received in the receiving space 18. Each of the mounting portions 16 depends from an end portion of the corresponding sidewall 14. In the illustrated embodiment, a distance between the frames 34, 38 is greater than a thickness of each of the sidewalls 14 of the shielding member 10.

In assembly, the mounting portions 16 of the shielding member 10 are soldered in the mounting holes 36 of the circuit board 30, respectively, so that the shielding member 10 and the circuit board 30 are assembled in an assembly. In this position, the frames 34, 38 surround the junction between the shielding member 10 and the circuit board 30.

Because the frames 34, 38 surround the junction between the sidewalls 14 and the circuit board 30, the electromagnetic waves radiated from the electronic component 32 cannot leak from the gaps between the sidewalls 14 and the circuit board 30, and also the electronic component 32 received in the shielding member 10 is protected from EMI.

While an embodiment of the present disclosure has been described, it should be understood that it has been presented by way of example only and not by way of limitation. Thus the breadth and scope of the present disclosure should not be limited by the above-described exemplary embodiments, but should be defined only in accordance with the following claims and their equivalents.

What is claimed is:

1. An electronic device comprising:
a circuit board comprising a pair of frames, a plurality of mounting holes disposed between the pair of frames, wherein the pair of frames surround at least one electronic component positioned within an area defined within the pair of frames; and
a shielding member to shield the electronic component from electromagnetic interference (EMI), the shielding member comprising a top wall, a plurality of sidewalls, and a plurality of mounting portions extending from end portions of the sidewalls, wherein the top wall and the sidewalls cooperatively bound a receiving space to receive the at least one electronic component, and wherein the mounting portions are received in the corresponding mounting holes to attach the shielding member to the circuit board.

2. The electronic device as claimed in claim 1, wherein each of the pair of frames is annular.

3. The electronic device as claimed in claim 2, wherein the frames surround a junction between the sidewalls and the circuit board.

4. The electronic device as claimed in claim 3, wherein each of the frames is made of soldering tin.

5. The electronic device as claimed in claim 4, wherein a height of each of the frames is about 0.1 mm, and wherein a width of each of the frames is about 0.25 mm.

6. The electronic device as claimed in claim 2, wherein the pair of frames comprises an inner framed surrounding the mounting holes, and an outer frame surrounding the inner frame.
